(19) United States
(12) Patent Application Publication
(10) Pub. No.: US 2009/0231806 A1
(43) Pub. Date: Sep. 17, 2009

(54) Casing for a Server

(76) Inventor: Guo-Wei Lee, Sijhih City (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 12/038,082

(22) Filed: Feb. 27, 2008

(51) Int. Cl. G06F 1/16; H05K 5/02; A47B 81/00

(52) U.S. Cl. 361/679.58; 312/223.2

(57) ABSTRACT

The present invention provides a casing for a server, including a casing body and a slide. There are pluralities of fastening-pin installed on one side of the casing body, wherein each one of the fastening-pins comprises a head and a body. The radial dimension of the heads is bigger than the radial dimension of the bodies. On the other side of the casing body dispose pluralities of first holes, wherein the first holes correspond to fastening-pins. In addition, the slide is installed inside the casing body near the first holes, wherein the end of the slide extends out of the casing body. There are pluralities of second holes disposed on the slide, wherein the bore diameter of the front of the second holes is bigger than the radial dimension of the heads of the fastening-pins, the bore diameter of the rear of the second holes is smaller than the radial dimension of the heads of the fastening-pins, and the rear of the second holes and the first holes are in the corresponding positions.

### BACKGROUND OF THE INVENTION

1. Field of the Invention

The present invention relates to a casing for a server. More particularly, the present invention relates to a casing which can be combined with other casings.

2. Description of the Prior Art

As the information technology proceeds, an information handling system is used in more and more occasions. Both individuals and companies can handle, save or transmit information through the information handling system. There are more and more users combining pluralities of servers in the increasing need of information handling system to save or transmit information.

In general, the servers are usually disposed in the server rack when the information handling system includes pluralities of servers. Please refer to FIG. 1 for a prior server rack. On each side of the server rack 10 are pluralities of holes 11, allowing users to fasten a slide 12 on parts of the holes 11 so as to install a server 100 on the slide 12. In order to enhance the capability of the information handling system, the users just have to install more servers, connecting these servers with each other.

Moreover, as the information technology proceeds, the users are longing for the size curtailment of the servers for the convenience of transport. However, it would make the servers with smaller width unsuitable for the present server rack 10, which means the users have to purchase another server rack with different dimensions, resulting in the increment of the cost. It would, therefore, be desirable to provide the present server rack 10 with the capability of installing servers with smaller dimensions without purchasing new server racks.

### SUMMARY OF THE INVENTION

The present invention provides a casing for a server, which can be combined alongside with other casings, so as to install more servers on the server rack.

In one aspect of the invention, the casing includes a casing body and a slide, wherein one side of the casing body disposed pluralities of fastening-pins. Each fastening-pin includes a head and a body, wherein the radial dimension of the heads is bigger than the radial dimension of the bodies. On the opposite side of the casing body dispose pluralities of first holes, which correspond to those fastening-pins. In addition, the slide is installed in a slippery manner inside the casing body near the first holes, wherein the slide has pluralities of second holes and the end of the slide extends out of the casing body. The bore diameter of the front of the second holes is bigger than the radial dimension of the heads, and the bore diameter of the rear of the second holes is smaller than the radial dimension of the heads. Moreover, the rear of the second holes and the first holes are in the corresponding positions.

The present casing further includes at least a barrier while the slide further includes at least a third hole. In addition, the barrier extends through the third hole. As the slide is pulled backward till the barrier contacts the edge of the terminal of the third hole, the front of the second holes and the first holes are then in the corresponding positions.

In the present casing, a screw is installed in the end of the slide so as to screw the slide to the rear of the casing body. In addition, the side wall of the screw has pluralities of grooves, so as to increase the friction between the screw and the fingers of users.

In the present casing, the fastening-pin is a screw.

In the present casing, the bore diameter of the front of the first holes is smaller than the radial dimension of the heads of the fastening-pin, and the bore diameter of the rear of the first holes is bigger than the radial dimension of the heads of the fastening-pin, wherein the front of the first holes and the fastening-pin are in the corresponding positions. In addition, as the slide is pulled backward till the barrier contacts the edge of the terminal of the third hole, the front of the second holes and the rear of the first holes are then in the corresponding positions.

The present casing further includes a carrier installed in the rear of the casing body.

The present casings for a server can be combined alongside with each other and then installed on the server rack. That is to say, servers with smaller width are still suitable for the present server rack with the help of the casings of the invention, which means there is no need to purchase another server rack with different dimensions. In addition, the present casing makes it possible to install more servers on the server rack.

### BRIEF DESCRIPTION OF THE DRAWINGS

The accompanying drawings are included to provide a her understanding of the invention, and are incorporated in and constitute a part of this specification. The drawings illustrate embodiments of the invention and, together with the description, serve to explain the principles of the invention.

FIG. 1 is a prior server rack.

FIG. 2 is a perspective view of a casing of the present embodiment.

FIG. 3 is a rear perspective view of a casing.

FIG. 4A is an internal perspective view of a casing.

FIG. 4B is a partial explosive view of a casing.

FIG. 5 is an internal perspective view of a casing after the slide is pulled backward.

FIG. 6A to FIG. 6C show the combination process of two casing.

FIG. 7 is a perspective view of casings with lock elements.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

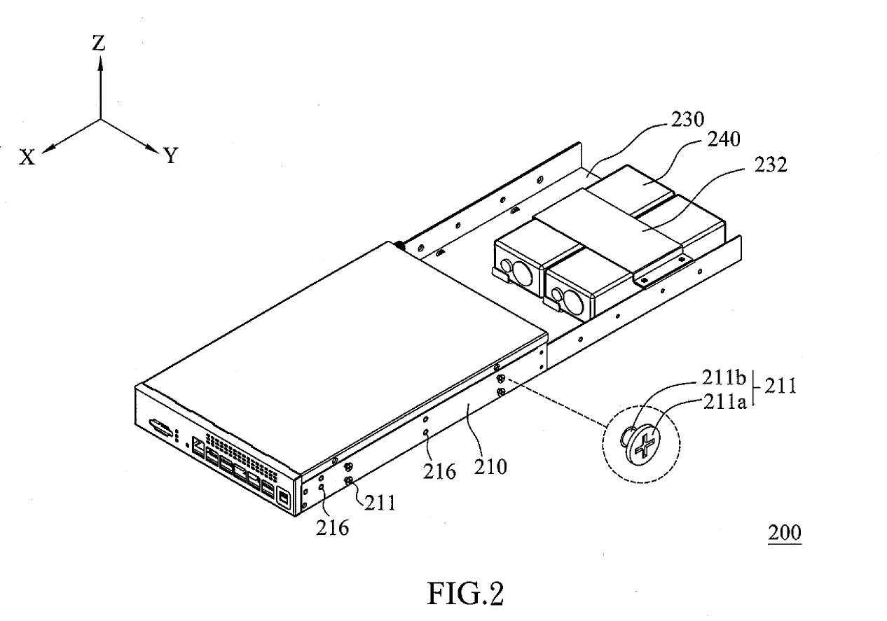

Please refer to FIG. 2 for a perspective view of a casing of the present embodiment. In the present embodiment, the casing 200 is a casing for a server. The casing 200 includes a casing body 210. On one side of the casing body 210 disposed pluralities of fastening-pins 211. The fastening-pin is a screw in the present embodiment. Each fastening-pin 211 includes a head 211a and a body 211b. The radial dimension of the heads 211a is bigger than the radial dimension of the bodies 211b. In addition, a carrier 230 on where a power supply 240 disposed can be installed in the rear of the casing body 210. The power supply 240 is fastened by a fastening mechanism 232 of the carrier 230. Moreover, the power supply 240 provides the electronic components (not depicted) in the casing 200 with sufficient power through wire (not depicted). The power supply 240 is disposed outside the casing body 210, which means there is more room inside the casing body 210 for electronic components.

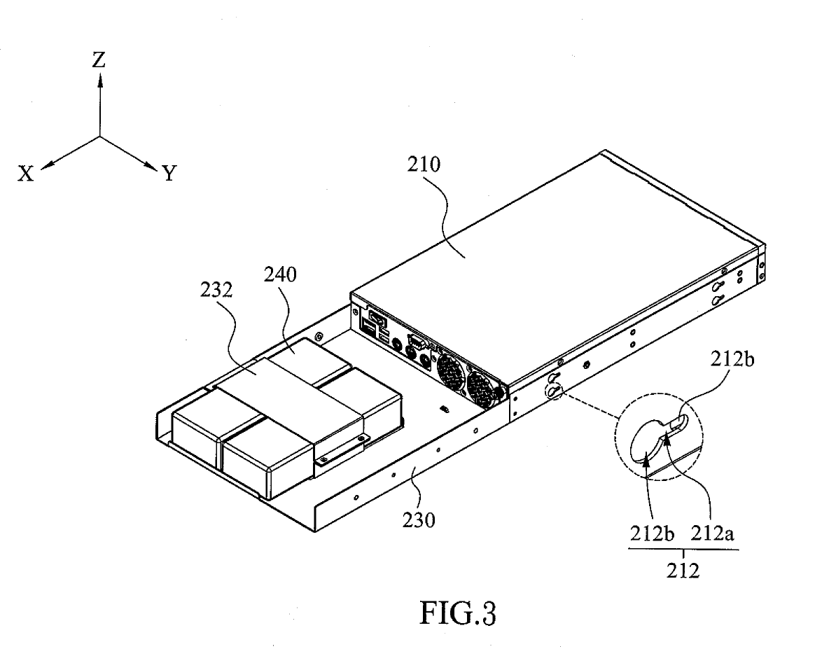

Please refer to FIG. 2 and FIG. 3 simultaneously, wherein the FIG. 3 is a rear perspective view of a casing. On the opposite side of the casing body 210 dispose pluralities of first holes 212. The bore diameter of the front 212a of the first holes 212 is smaller than the radial dimension of the heads 211a of the fastening-pins 211, and the bore diameter of the rear 212b of the first holes 212 is bigger than the radial dimension of the heads 211a of the fastening-pins 211. In the present embodiment, the front 212a of the first holes 212 and the fastening-pins 211 are in the corresponding positions. That is to say, the position of the front 212a of the first holes 212 and the position of the fastening-pins 211 are substantially the same in the X-axis and the Z-axis direction.

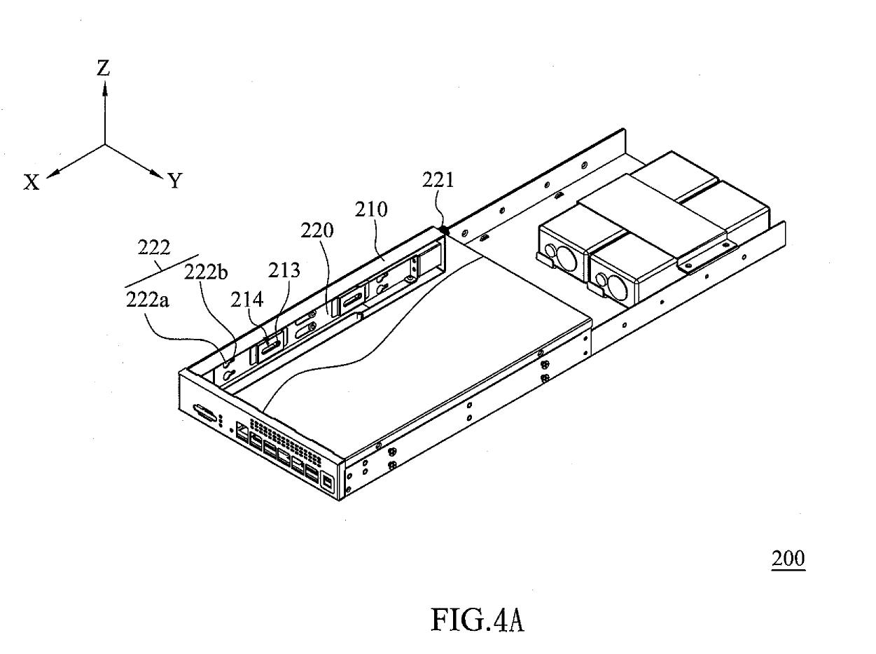

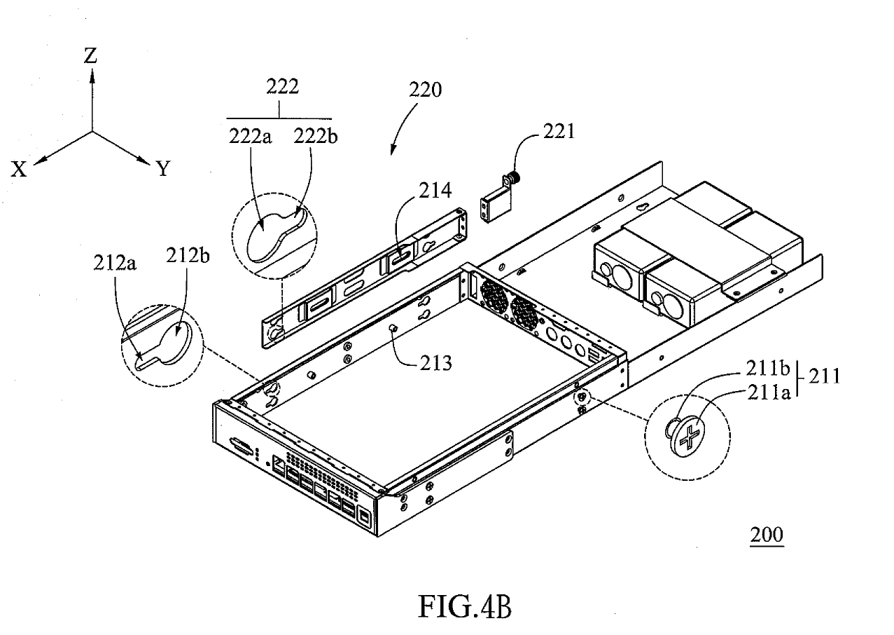

Then, refer to FIG. 4A and FIG. 4B for an internal perspective view and a partial explosive view of a casing respectively. A slide 220 is installed in a slippery manner inside the casing body 210 near the first holes 212, wherein a screw 221 is installed in the end of the slide 220 so as to screw the slide 220 to the rear of the casing body 210. There are still pluralities of second holes 222 corresponding to the first holes 212. In the present embodiment, the front 212a of the first holes 212 and the rear 222b of the second holes 222 are in the corresponding positions. That is to say, the position of the front 212a of the first holes 212 and the position of the rear 222b of the second holes 222 are substantially the same in the X-axis and the Z-axis direction. Moreover, the bore diameter of the front 222a of the second holes 222 is bigger than the radial dimension of the heads 211a of the fastening-pins 211, and the bore diameter of the rear 222a of the second holes 222 is smaller than the radial dimension of the heads 221a of the fastening-pins 211.

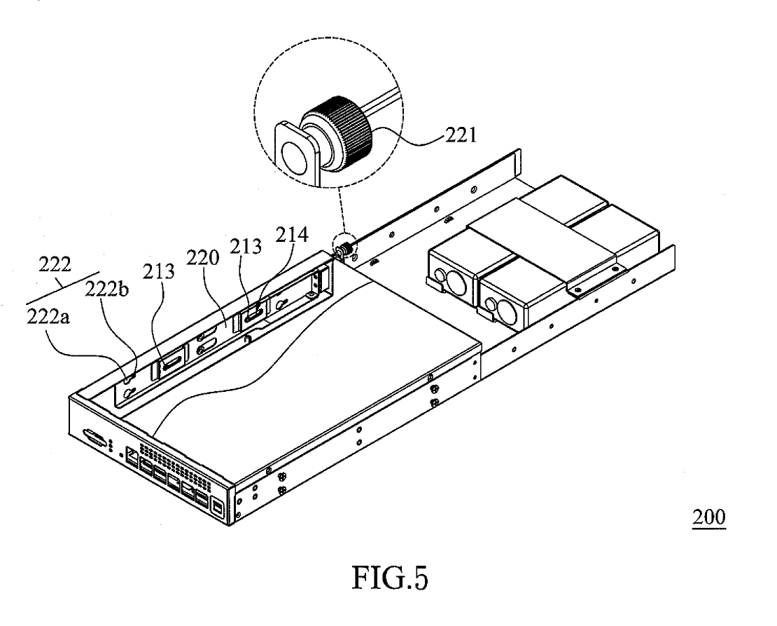

Moreover, please refer to FIG. 5 for an internal perspective view of a casing after the slide is pulled backward. As the screw 221 loosened, the users can slide the slide 220 back and forth inside the casing body 210. In addition, the side wall of the screw 221 has pluralities of grooves so as to increase the friction between the screw 221 and the fingers of users. That is to say, the users can loosen the screw 221 barehanded without any help of a screwdriver.

Please refer to FIG. 4A and FIG. 4B once again. There are still pluralities of barriers 213 installed on the internal surface of the casing body 210. The slide 220 further includes pluralities of third holes 214. The barriers 213 extend through the third holes 214. Now please refer to FIG. 4A, FIG. 4B and FIG. 5 simultaneously. When the slide 220 is pulled backward till the barriers 213 contact the edge of the terminals of the third holes 214, the front 222a of the second holes 222 and the rear 212b of the first holes 212 are in the corresponding positions.

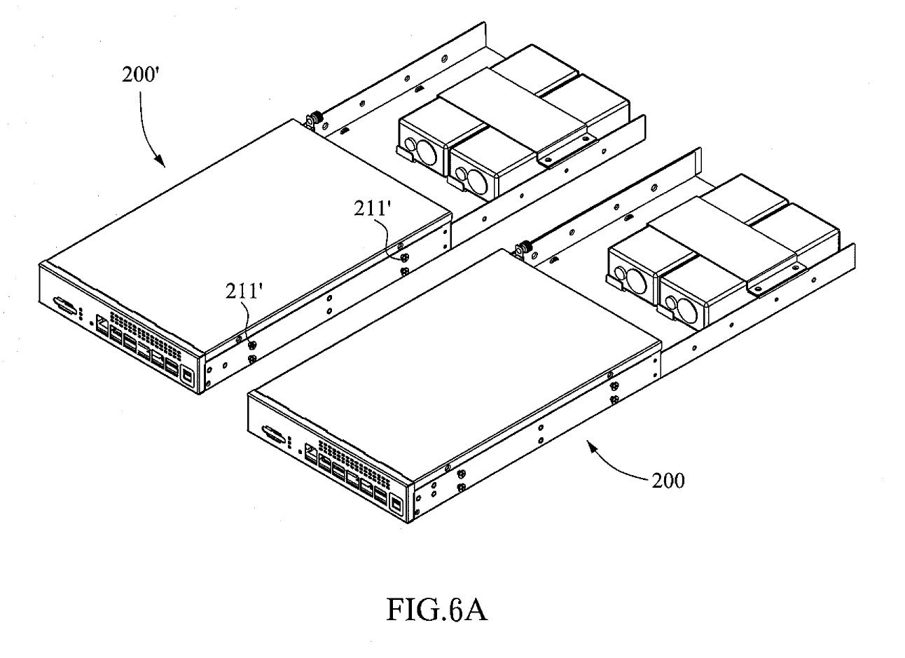

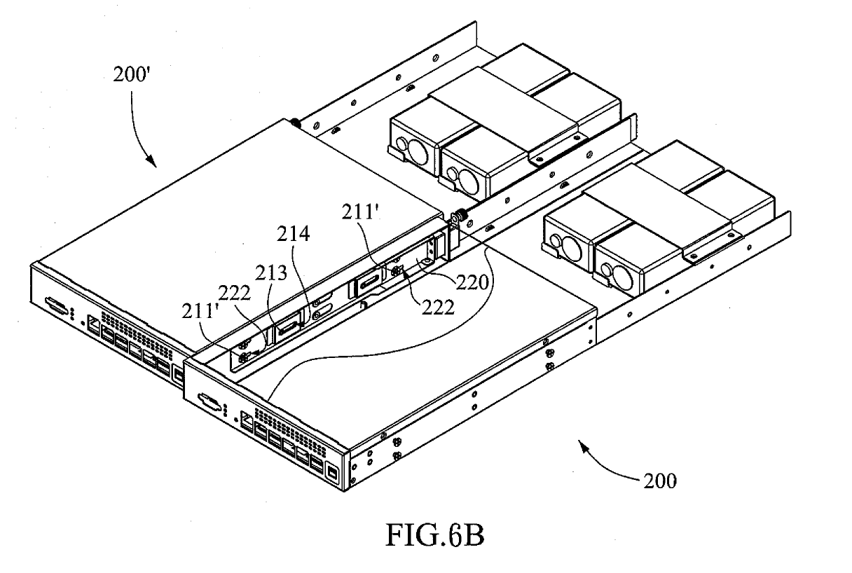

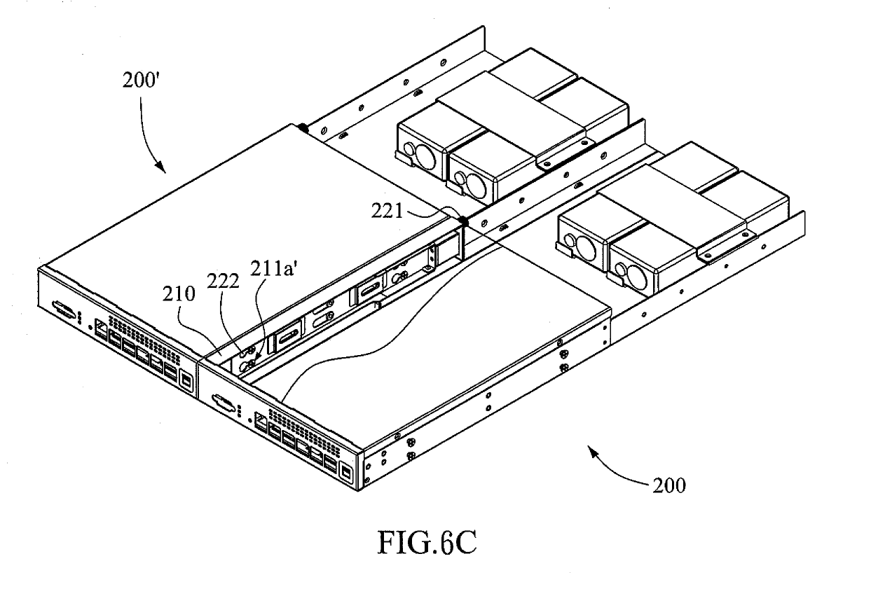

The following paragraphs describe how to combine two casings of the present embodiment alongside. Please refer to FIG. 6A to FIG. 6C for the combination process of two casing. Please refer to FIG. 6A first. A casing 200 and a casing 200′ are two identical casings. Before the combination, the rear 212b of the first holes 212 of the casing 200 (as depicted in FIG. 3 or FIG. 4B) and the fastening-pin 211′ of the casing 200′ must be in the corresponding positions. Next, the casings 200 and 200′ are drawn near to each other so as to extend the fastening-pins 211′ of the casing 200′ through the first holes 212.

Then, please refer to FIG. 4B and FIG. 6B simultaneously. To extend the fastening-pins 211′ through the second holes 222, the users have to slide the slide 220 backward till the barriers 213 contact the terminals of the third holes. Then, the front 222a of the second holes 222 and the rear 212b of the first holes 212 are in the corresponding positions, with the result that the fastening-pins 211′ extend through the first holes 212 of the casing 200 as well as the second holes 222 of the slide 220 at the same time.

Moreover, please refer to FIG. 4B and FIG. 6C. As the fastening-pins 211′ extend through the second holes 222, the users can move the casing 200 backward while pull the slide 200 forward to preliminerily combine the two casings 200 and 200′. Then, screw the screw 210 to the rear of the casing body 210. Meanwhile, the rear 222b of the second holes 222 and the fastening-pin 211′ are in the corresponding positions. Because the bore diameter of the rear 222b of the second holes 222 is smaller than the radial dimension of the heads 211a′ of the fastening-pins 211, the heads 211a′ of the fastening-pins 211 are then stuck inside the casing body 210 with the result that the casings 200 and 200′ are combined fast.

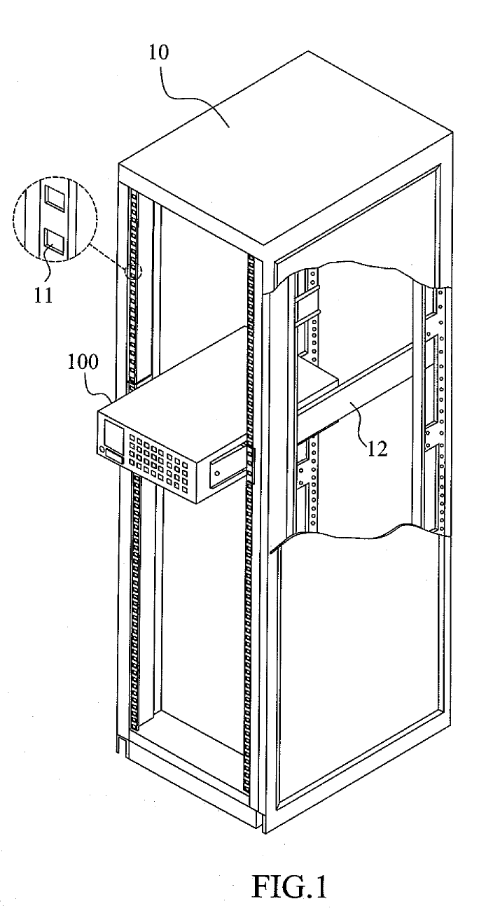

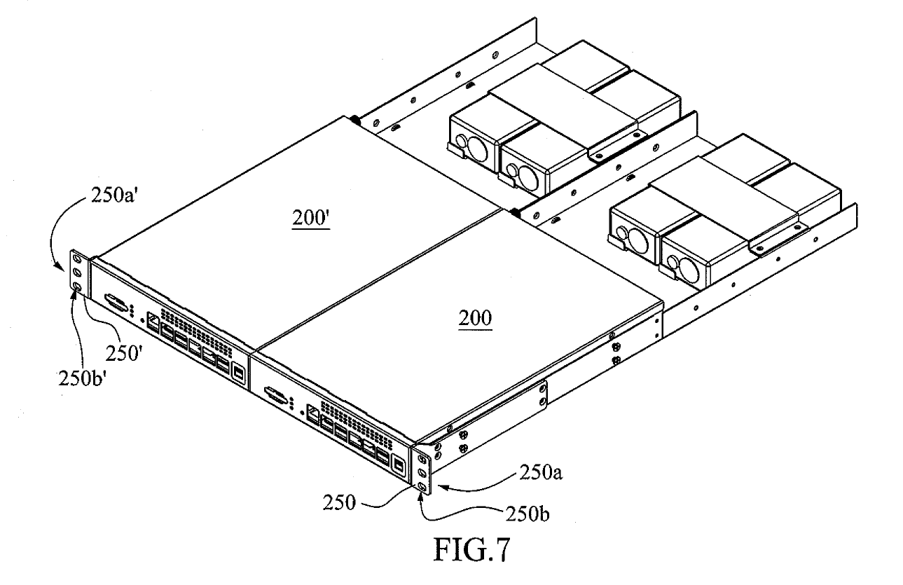

Then, refer to FIG. 2 and FIG. 7 for casings with lock elements. After combining the casings 200 and 200′, the users have to install lock elements to dispose the casing assembly on the server rack 10. On both side of the combination of the casings 200 and 200′ are pinholes 216 on where the lock elements 250 and 250′ are installed respectively. In addition, the noses 250a, 250a′ of the lock elements 250, 250′ have pluralities of pinholes 250b, 250b′. After installing the lock elements 250, 250′ on the casings 200, 200′, the users can lock the casings 200, 200′ to the server rack 10 depicted in FIG. 1. Moreover, the users can also use other fastening means, such as a slide, to install the casings 200 and 200′ on the server rack.

Several points for attention, the present embodiment depicts the combination of two casings, yet those skilled in the art can combine more servers together if necessary. Moreover, there is no need to purchase another server rack with different dimensions when servers with smaller width are to be installed. As the casings are combined fast, the casings can be installed on the server rack. In addition, the users can install more servers on the server rack by using the present casing.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

I claim:

1. A casing for a server, comprising:
a casing body, wherein on one side of the casing body are installed pluralities of and the radial dimension of the heads is bigger than the radial dimension of the bodies; and, on the other side of the casing body are disposed pluralities of first holes, wherein the first holes and the fastening-pins are in the corresponding positions; and
a slide, installed in a slippery manner inside the casing body near the first holes, wherein the end of the slide extends out of the casing body and pluralities of second holes are disposed on the slide, wherein the bore diameter of the front of the second holes is bigger than the radial dimension of the heads of the fastening-pin, the bore diameter of the rear of the second holes is smaller than the radial dimension of the heads of the fastening-pin, and the rear of the second holes and the first holes are in the corresponding positions.

2. The casing for a server according to claim 1, wherein the casing body further comprises at least a barrier and the slide further comprises at least a third hole, wherein the barrier extends through the third hole and when the slide is pulled backward till the barrier contacts the edge of the terminal of the third hole, the front of the second holes and the first holes are then in the corresponding positions.

3. The casing for a server according to claim 1, wherein a screw is installed in the end of the slide, so as to screw the slide to the rear of the casing body.

4. The casing for a server according to claim 3, wherein the side wall of the screw has pluralities of grooves to increase the friction between the screw and the fingers of a users.

5. The casing for a server according to claim 1, wherein the fastening-pins are screws.

6. The casing for a server according to claim 1, wherein the bore diameter of the front of the first holes is smaller than the radial dimension of the heads of the fastening-pins and the bore diameter of the rear of the first holes is bigger than the radial dimension of the heads of the fastening-pins, wherein the front of the first holes and the fastening-pins are in the corresponding position, and the front of the second holes and the rear of the first holes are in the corresponding positions when the slide is pulled backward till the barrier contacts the terminal of the third hole.

7. The casing for a server according to claim 1, wherein the casing further comprises a carrier installed on the rear of the casing body, and the carrier disposes at least a power supply.

8. The casing for a server according to claim 1, wherein a fastening means is installed on the side of the casing so as to fasten the casing to a server rack.
